(19) United States
(12) Patent Application Publication
(10) Pub. No.: US 2022/0392813 A1
(43) Pub. Date: Dec. 8, 2022

(54) CONTROL METHOD AND CONTROL APPARATUS

(71) Applicant: Tokyo Electron Limited, Tokyo (JP)

(72) Inventors: Akira HIRATA, Iwate (JP); Tatsuya YAMAGUCHI, Iwate (JP)

(21) Appl. No.: 17/828,384

(22) Filed: May 31, 2022

(30) Foreign Application Priority Data
Jun. 7, 2021 (JP) 2021-095287

(51) Int. Cl. H01L 21/66; H01L 21/67

(52) U.S. Cl. CPC H01L 22/20; H01L 21/67109; H01L 21/67017

(57) ABSTRACT

A control method of a film forming apparatus includes (a) acquiring a first temperature measured by a first temperature sensor in a tubular member in a processing container of the film forming apparatus; (b) calculating a first power to be output to a heating unit disposed in the processing container; (c) acquiring a second temperature measured by a second temperature sensor provided outside the tubular member in the processing container; (d) calculating a second power to be output to the heating unit; (e) calculating a predicted value of the second temperature at a predetermined time ahead, from the second temperature based on a prediction model; (f) outputting either the first power or the second power to the heating unit according to the predicted value of the second temperature; and (g) repeating (a) to (f) in a predetermined cycle.

### CROSS-REFERENCE TO RELATED APPLICATIONS

This application is based on and claims priority from Japanese Patent Application No. 2021-095287, filed on Jun. 7, 2021 with the Japan Patent Office, the disclosure of which is incorporated herein in its entirety by reference.

### TECHNICAL FIELD

The present disclosure relates to a control method and a control apparatus.

### BACKGROUND

It has been proposed, for example, to measure the temperature in a processing container of a semiconductor manufacturing apparatus and to use the results of measurement for the control of process conditions of a substrate processing executed in the processing container (see, e.g., Japanese Patent Laid-Open Publication No. 2004-172409).

### SUMMARY

An aspect of the present disclosure is a control method of a film forming apparatus including (a) acquiring a first temperature measured by a first temperature sensor in a tubular member in a processing container of the film forming apparatus, (b) calculating a first power to be output to a heating unit disposed in the processing container such that the first temperature approaches a target temperature based on the acquired first temperature, (c) acquiring a second temperature measured by a second temperature sensor provided outside the tubular member in the processing container, (d) calculating a second power to be output to the heating unit such that the second temperature approaches an upper temperature limit based on the acquired second temperature, (e) calculating a predicted value of the second temperature at a predetermined time ahead, from the acquired second temperature based on a prediction model that predicts at least the second temperature, (f) outputting either the first power or the second power to the heating unit according to the calculated predicted value of the second temperature, and (g) repeating (a) to (f) in a predetermined cycle.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional diagram illustrating an example of a heat treatment apparatus according to an embodiment.

FIGS. 2A to 2C are diagrams for explaining the problem of an excessive temperature rise inside a processing container.

FIGS. 3A and 3B are diagrams illustrating an outline of a control method of a heat treatment apparatus according to a first embodiment.

FIG. 4 is a diagram illustrating an example of a control apparatus of the heat treatment apparatus according to the first embodiment.

FIG. 5 is a diagram illustrating a configuration and one operation example of a control unit of the control apparatus according to the first embodiment.

FIG. 6 is a diagram illustrating a configuration and Operation Example 1 of a prediction unit of the control apparatus according to the first embodiment.

FIG. 7 is a diagram illustrating a configuration and Operation Example 2 of the prediction unit of the control apparatus according to the first embodiment.

FIG. 8 is a diagram illustrating a configuration and Operation Example 3 of the prediction unit of the control apparatus according to the first embodiment.

FIGS. 9A to 9C are diagrams illustrating an example of the simulation results by control according to Comparative Example 1.

FIGS. 10A to 10C are diagrams illustrating an example of the simulation results by control according to Comparative Example 2.

FIGS. 11A to 11C are diagrams illustrating an example of the simulation results by the control apparatus according to the first embodiment.

FIG. 12 is a diagram illustrating a configuration and one operation example of the control unit of the control apparatus according to a second embodiment.

FIGS. 13A to 13C are diagrams illustrating an example of the simulation results by the control apparatus according to the second embodiment.

FIG. 14 is a diagram illustrating an example of a hardware configuration of the control apparatus according to an embodiment.

### DESCRIPTION OF EMBODIMENT

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same components will be designated by the same reference numerals, and duplicated descriptions thereof may be omitted.

[Heat Treatment Apparatus]

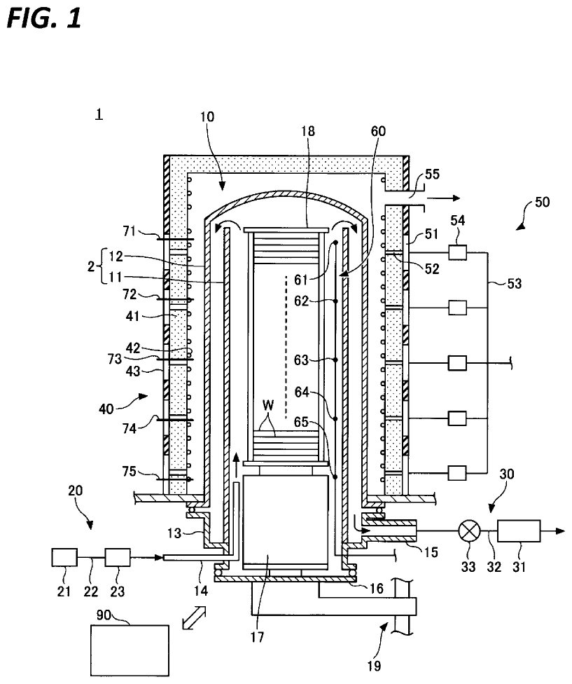

A heat treatment apparatus 1 will be described as an example of a film forming apparatus according to an embodiment with reference to FIG. 1. FIG. 1 is a schematic diagram illustrating an example of the heat treatment apparatus 1 according to an embodiment.

The heat treatment apparatus 1 includes a processing container 10 and a tubular member 2. The processing container 10 has a substantially cylindrical shape. The tubular member 2 is disposed in the processing container 10, and includes an inner tube 11 and an outer tube 12. The inner tube 11 has a substantially cylindrical shape. The inner tube 11 is formed of, for example, a heat resistant material such as quartz. The inner tube 11 accommodates a substrate. The inner tube 11 is also called an inner tube.

The outer tube 12 has a substantially cylindrical shape with a ceiling, and is provided concentrically around the inner tube 11. The outer tube 12 is formed of, for example, a heat resistant material such as quartz. The outer tube 12 is also called an outer tube. The heat treatment apparatus 1 has a double structure with the tubular member 2 and the processing container 10.

The heat treatment apparatus 1 includes a manifold 13, an injector 14, a gas outlet 15, and a lid body 16. The manifold 13 has a substantially cylindrical shape. The manifold 13 supports the lower ends of the inner tube 11 and the outer tube 12. The manifold 13 is formed of, for example, stainless steel.

The injector 14 extends horizontally in the inner tube 11 through the manifold 13, and is bent in an L-shaped manner in the inner tube 11 to extend upward. A base end of the injector 14 is connected to a gas supply pipe 22 to be described later, and a tip end thereof is open. The injector 14 discharges a processing gas introduced through the gas supply pipe 22 into the inner pipe 11 from an opening in the tip end thereof. The processing gas includes, for example, a film forming gas, a cleaning gas, and a purge gas. In the present embodiment, the film forming gas is a gas used for forming a molybdenum film. The example of FIG. 1 illustrates a case where there is one injector 14, but there may be a plurality of injectors 14.

The gas outlet 15 is formed in the manifold 13. An exhaust pipe 32 is connected to the gas outlet 15. The processing gas supplied into the processing container 10 is exhausted by an exhaust unit 30 through the gas outlet 15.

The lid body 16 hermetically blocks an opening in the lower end of the manifold 13. The lid body 16 is formed of, for example, stainless steel. A wafer boat 18 is placed on the lid body 16 via a heat insulating cylinder 17. The heat insulating cylinder 17 and the wafer boat 18 are formed of, for example, a heat resistant material such as quartz. The wafer boat 18 holds a plurality of wafers W substantially horizontally at a predetermined interval in the vertical direction. The wafer boat 18 is carried (loaded) into the processing container 10 by an elevating mechanism 19 raising the lid body 16 and is accommodated in the processing container 10. The wafer boat 18 is carried out (unloaded) from the processing container 10 by the elevating mechanism 19 lowering the lid body 16. The wafer W is an example of a substrate.

The heat treatment apparatus 1 further includes a gas supply unit 20, the exhaust unit 30, a heating unit 40, a cooling unit 50, and a control apparatus 90. The gas supply unit 20 includes a gas source 21, the gas supply pipe 22, and a flow rate control unit 23. The gas source 21 is a source of the processing gas, and includes, for example, a film forming gas source, a cleaning gas source, and a purge gas source. The gas supply pipe 22 connects the gas source 21 to the injector 14. The flow rate control unit 23 is fitted into the gas supply pipe 22 and controls the flow rate of the gas flowing through the gas supply pipe 22. The flow control unit 23 includes, for example, a mass flow controller and an on/off valve. Such a gas supply unit 20 controls the flow rate of the processing gas from the gas source 21 with the flow rate control unit 23 and supplies the processing gas to the injector 14 through the gas supply pipe 22.

The exhaust unit 30 includes an exhaust device 31, an exhaust pipe 32, and a pressure controller 33. The exhaust device 31 is, for example, a vacuum pump such as a dry pump or a turbo molecular pump. The exhaust pipe 32 connects the gas outlet 15 to the exhaust device 31. The pressure controller 33 is fitted into the exhaust pipe 32 and controls the pressure in the processing container 10 by adjusting the conductance of the exhaust pipe 32. The pressure controller 33 is, for example, an automatic pressure control valve.

The heating unit 40 includes a heat insulating material 41, a heater 42, and an outer shell 43. The heat insulating material 41 has a substantially cylindrical shape and is provided around the outer tube 12. The heat insulating material 41 is formed of silica and alumina as main components. The heater 42 is an example of a heat generating element and is provided on the inner periphery of the heat insulating material 41. The heater 42 is provided on the sidewall of the processing container 10 in a linear or planar shape so as to be divided into a plurality of zones in the height direction of the processing container 10, thereby enabling temperature control. The outer shell 43 is provided to cover the outer periphery of the heat insulating material 41. The outer shell 43 maintains the shape of the heat insulating material 41 and reinforces the heat insulating material 41. The outer shell 43 is formed of a metal such as stainless steel. Further, in order to suppress the influence of heat on the outside of the heating unit 40, a water cooling jacket (not illustrated) may be provided on the outer periphery of the outer shell 43. In such a heating unit 40, the amount of heat generated by the heater 42 is determined by the power supplied to the heater 42, and thus, the heating unit 40 heats the inside of the processing container 10 to a desired temperature.

The cooling unit 50 supplies a cooling fluid toward the processing container 10 to cool the wafer W in the processing container 10. The cooling fluid may be, for example, air. The cooling unit 50 supplies the cooling fluid toward the processing container 10, for example, when the wafer W is rapidly lowered in temperature after a heat treatment. The cooling unit 50 includes a fluid flow path 51, a blowout hole 52, a distribution flow path 53, a flow rate regulator 54, and a heat exhaust port 55.

A plurality of fluid flow paths 51 are formed in the height direction between the heat insulating material 41 and the outer shell 43. The fluid flow paths 51 are, for example, flow paths formed along the circumferential direction at the outside of the heat insulating material 41.

The blowout hole 52 is formed through the heat insulating material 41 from each fluid flow path 51 and blows out the cooling fluid into the space between the outer tube 12 and the heat insulating material 41.

The distribution flow path 53 is provided outside the outer shell 43 and distributes and supplies the cooling fluid to each fluid flow path 51.

The flow rate regulator 54 is fitted into the distribution flow path 53 and regulates the flow rate of the cooling fluid supplied to the fluid flow path 51.

The heat exhaust port 55 is provided above a plurality of blowout holes 52 and discharges the cooling fluid supplied to the space between the outer tube 12 and the heat insulating material 41 to the outside of the heat treatment apparatus 1. The cooling fluid discharged to the outside of the heat treatment apparatus 1 is cooled by, for example, a heat exchanger, and is supplied to the distribution flow path 53 again. However, the cooling fluid discharged to the outside of the heat treatment apparatus 1 may be discharged without being reused.

The temperature sensor 60 is an example of a first temperature sensor that detects the temperature in the tubular member 2. The temperature sensor 60 is provided in, for example, the inner tube 11. However, the temperature sensor 60 may be provided at a position where it is capable of detecting the temperature in the tubular member 2, and may be provided in, for example, the space between the inner tube 11 and the outer tube 12. The temperature sensor 60 includes, for example, a plurality of temperature measuring units 61 to 65 provided at different positions in the height direction corresponding to the plurality of zones. The temperature measuring units 61 to 65 are provided to correspond to the zones “TOP,” “C-T,” “CTR,” “C-B,” and “BTM,” respectively. The temperature measuring units 61 to 65 may be, for example, thermocouples or temperature measuring resistors. The temperature sensor 60 transmits the temperature detected by the temperature measuring units 61 to 65 to the control apparatus 90.

Temperature sensors 71 to 75 (hereinafter, collectively referred to as a “temperature sensor 70”) are inserted into the space between the processing container 10 and the tubular member 2 from the outside of the processing container 10. Thus, temperature measuring units of the temperature sensor 70 are arranged at substantially the same heights as the temperature measuring units 61 to 65 to correspond to the zones “TOP,” “C-T.” “CTR.” “C-B,” and “BTM.” Each of the temperature measuring units of the temperature sensor 70 may be, for example, a thermocouple or a temperature measuring resistor. The temperature sensor 70 transmits the temperature detected by the temperature measuring units to the control apparatus 90.

The number of temperature measuring units of the temperature sensors 60 and 70 is not limited to five, but may be seven or other one or more. The temperature sensor 70 is located near the heater 42, and the heater 42 is paired with the temperature measuring units of the temperature sensor 70 and the temperature sensor 60. The temperature in the tubular member 2 measured by the temperature sensor 60 is also referred to as an “inner temperature” or “TI.” The inner temperature (TI temperature) measured by the temperature sensor 60 is an example of a first temperature. The temperature in the processing container 10 outside the tubular member 2 measured by the temperature sensor 70 is referred to as an “outer temperature” or “TO.” The outer temperature (TO temperature) measured by the temperature sensor 70 is an example of a second temperature.

The control apparatus 90 controls an operation of the heat treatment apparatus 1. The control apparatus 90 may be, for example, a computer. A computer program for the implementation of the entire operation of the heat treatment apparatus 1 is stored in a storage medium. The storage medium may be, for example, a flexible disk, a compact disk, a hard disk, a flash memory, or a DVD.

[Excessive Rise in Outer Temperature]

Usually, in the heat treatment apparatus 1, the temperature (inner temperature) of the region (hereinafter, also referred to as an “inner region”) in the tubular member 2 is raised to a target temperature set in a recipe to perform a desired film forming processing on the wafer W. At this time, by controlling the power of the heater 42 provided in the region (hereinafter, also referred to as an “outer region”) in the processing container 10 outside the tubular member 2, heat is transferred from the outer region to the inner region to raise the inner temperature to the target temperature.

However, in a case where a metal film having a high reflectance such as a molybdenum (Mo) film is formed on the wafer W by the heat treatment apparatus 1, the molybdenum film is adhered to the tubular member 2 (the surface of the inner tube 11 and the inner surface of the outer tube 11) upon the formation of the molybdenum film. Since the reflectance of the molybdenum film is as high as about 0.97, the molybdenum film adhered to the inside of the tubular member 2 functions as a reflective film. When the surface of the inner tube 11 and the inner surface of the outer tube 12 are covered with such a high reflectance film, the heat insulation effects due to the double structure of the tubular member 2 are enhanced, and it takes a time to transfer heat from the outer region to the inner region.

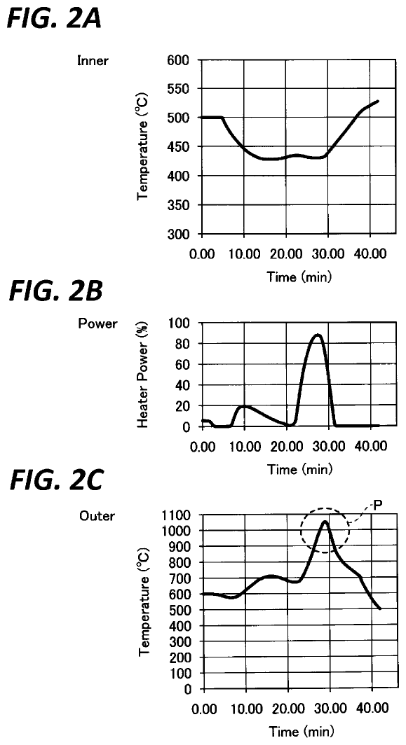

FIGS. 2A to 2C are graphs for explaining the problem of an excessive temperature rise inside the processing container 10. FIG. 2A is a graph illustrating an example of the inner temperature, the horizontal axis of the graph being the time and the vertical axis being the temperature. The inner temperature is rising gradually by controlling the power of the heater 42 illustrated in FIG. 2B.

However, since the molybdenum film adhered to the inside of the tubular member 2 functions as a reflective film, and it takes a time to transfer heat from the outer region to the inner region due to the double structure of the tubular member 2, the inner temperature does not rise immediately even when the power of the heater 42 is increased. Therefore, the power of the heater 42 is further increased. In the example of FIG. 2B, the power of the heater 42 is further increased when the time is less than 30 minutes.

Thus, a state where an excessive temperature rise in which the outer temperature exceeds a preset excess temperature occurs is represented by P in FIG. 2C. FIG. 2C is a graph illustrating an example of the outer temperature, the horizontal axis of the graph being the time and the vertical axis being the temperature. The outer temperature exceeded the excess temperature (1,050° C.) in less than 30 minutes due to an increase in the power of the heater 42. When the excess temperature is exceeded, the heater 42 is shut down to stop heating by the heater 42 due to a safety problem.

In order to avoid the excessive rise in the outer temperature described above, it is also conceivable to control the power of the heater 42 so as to slowly raise the inner temperature. In doing so, the outer temperature does not exceed the excess temperature, but it takes a time to raise the inner temperature to the target temperature, which deteriorates productivity. In consideration of productivity, it is desired to raise the inner temperature to the target temperature as quickly as possible while avoiding the excessive temperature rise.

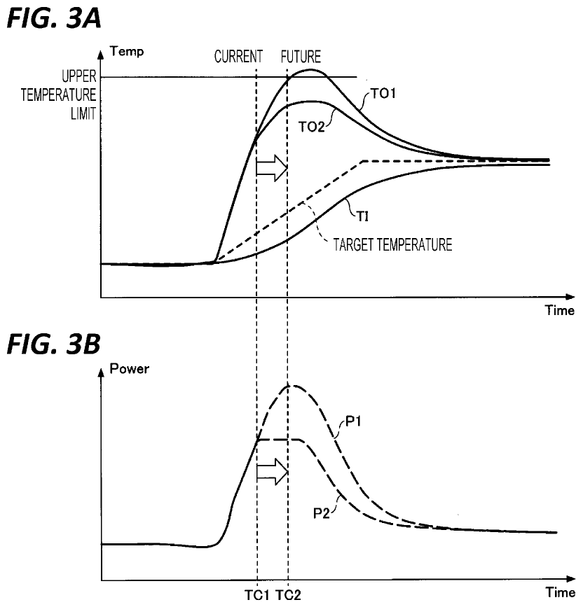

Hence, in a control method of a film forming apparatus according to the present disclosure, it is proposed to smoothly raise the inner temperature while avoiding an excessive rise in the outer temperature. FIGS. 3A and 3B illustrate an outline of a control method of the heat treatment apparatus 1 according to a first embodiment. In a process of forming a metal film having a high reflectance, since the inner temperature TI in FIG. 3A rises slowly, it takes a time until it approaches a target temperature. Thus, as a result of increasing the power of the heater 42 as represented by the curve P1 in FIG. 3B, the outer temperature TO1 in FIG. 3A exceeds the upper temperature limit (excessive rise in the outer temperature).

Hence, in the control method of the present disclosure, the outer temperature at a time point TC2 a predetermined time ahead of the current time point TC1 illustrated in FIGS. 3A and 3B is predicted. Then, in a case where a predicted value of the outer temperature exceeds the upper temperature limit, when the power is increased as it is as represented by the curve P1 in FIG. 3B, it can be predicted that the outer temperature will exceed the upper temperature limit after the predetermined time elapses as represented by the curve TO1 in FIG. 3A. In this case, the power of the heater 42 starts to be suppressed at the current time point TC1 as represented by the curve P2 in FIG. 3B. The upper temperature limit is set to a temperature lower than the excess temperature at which the heater 42 is shut down. Thus, a temperature rise in the outer temperature may be avoided as represented by the temperature curve TO2 in FIG. 3A. As a result, a deterioration in productivity may be prevented without shutting down the heater 42 due to the outer temperature exceeding the upper temperature limit. Hereinafter, a control method of the heat treatment apparatus 1 capable of avoiding an excessive temperature rise inside the processing container 10 without causing a delay in temperature control in the film forming apparatus will be described in the order of a first embodiment and a second embodiment. The control method of the heat treatment apparatus 1 is executed by the control apparatus 90. Thus, the control method of the heat treatment apparatus 1 will be described by explaining a configuration and operation of the control apparatus 90.

### First Embodiment

[Control Device]

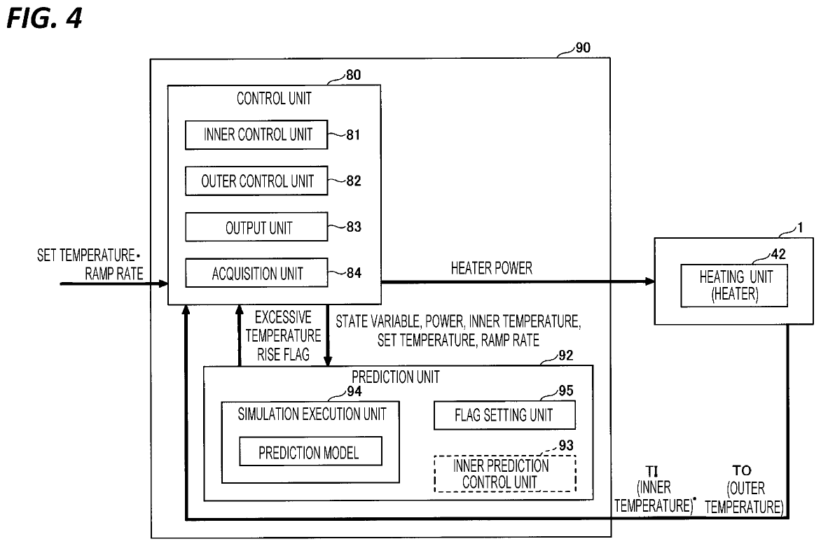

An outline of the configuration and operation of the control apparatus 90 of the heat treatment apparatus 1 according to a first embodiment will be described with reference to FIG. 4. FIG. 4 is a diagram illustrating an example of the control apparatus of the heat treatment apparatus according to the first embodiment. The control apparatus 90 includes respective functional units including a control unit 80 and a prediction unit 92. The control unit 80 acquires a set temperature and a ramp rate set in a recipe. The control unit 80 outputs the set temperature, ramp rate, state variable, power, and inner temperature to the prediction unit 92, and the prediction unit 92 inputs these pieces of information. The state variable is information on the inner temperature and the outer temperature, and the power is information on the power applied to the heater 42 as a command value (control input value) to the heater 42. The prediction unit 92 calculates a predicted value of the outer temperature at a predetermined time ahead according to a prediction model based on these pieces of information. The prediction unit 92 may also calculate a predicted value of the inner temperature at a predetermined time ahead, based on these pieces of information.

The prediction unit 92 sets 1 to an excessive temperature rise flag when it is predicted that the outer temperature at the predetermined time ahead will exceed the upper temperature limit based on the calculated predicted value of the outer temperature. The initial value of the excessive temperature rise flag is 0. The prediction unit 92 outputs the excessive temperature rise flag to the control unit 80, and the control unit 80 inputs the excessive temperature rise flag. The control unit 80 outputs either a first power or a second power calculated by the control unit 80 to the heater 42 as a command value based on the excessive temperature rise flag set by the prediction unit 92. The first power and the second power calculated by the control unit 80 will be described later.

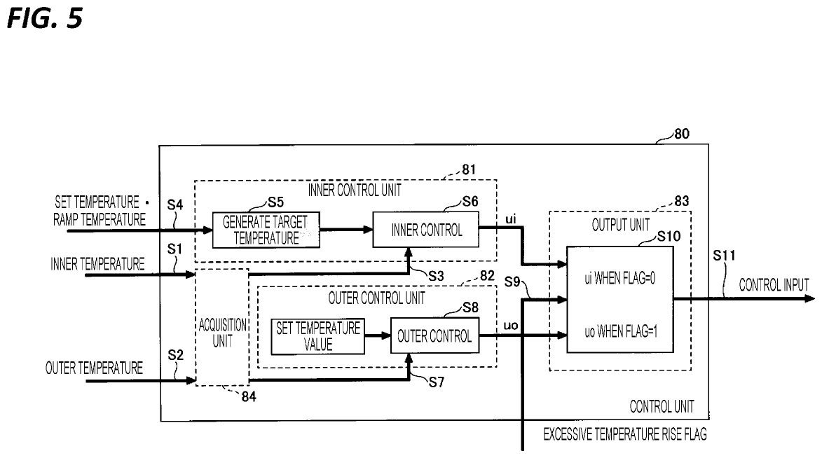

The temperature measuring unit of the temperature sensor 60 measures the TI temperature, which is the inner temperature, and feeds it back to the control unit 80. The temperature measuring unit of the temperature sensor 70 measures the TO temperature, which is the outer temperature, and feeds it back to the control unit 80. The prediction of the prediction unit 92 repeats the calculation of a predicted value of the outer temperature, for example, 1 minute ahead every 4 seconds. The temperature measuring units of the temperature sensors 60 and 70 repeatedly measure the TI temperature and the TO temperature at a set monitoring cycle and feed them back to the control unit 80. However, 4 seconds is an example of a predetermined cycle, and the predicted value of the outer temperature 1 minute ahead is an example of the prediction of the outer temperature at the predetermined time ahead, but not limited thereto. Each unit of the control unit (an acquisition unit 84, an inner control unit 81, an outer control unit 82, and an output unit 83 in FIG. 5) and prediction unit 92 of the control apparatus 90 repeatedly perform an operation of each of these units at a predetermined cycle.

(Control Unit)

A configuration and one operation Example of the control unit 80 will be described with reference to FIGS. 4 and 5. FIG. 5 illustrates the control unit 80 according to the first embodiment. The control unit 80 includes the inner control unit 81, the outer control unit 82, the output unit 83, and the acquisition unit 84. The acquisition unit 84 acquires the inner temperature (TI temperature) measured by the temperature sensor 60 in the tubular member 2 provided in the heat treatment apparatus 1 (step S1). Further, the acquisition unit 84 acquires the outer temperature (TO temperature) measured by the temperature sensor 70 in the processing container 10 outside the tubular member 2 (step S2). The measured inner temperature and outer temperature may be acquired repeatedly at timings corresponding to a predetermined cycle (e.g., 4 seconds), or may be acquired repeatedly at any other timings.

The inner control unit 81 inputs the acquired measured value of the inner temperature (step S3). Further, the inner control unit 81 inputs the set temperature and the ramp rate (step S4). When it is desired to control the inner temperature to 300° C. with respect to the temperature of 200° C. at a given time point (current time point), 200° C. and 300° C. are set as the set temperature. The ramp rate is the gradient by which the temperature is to be raised when controlling the temperature from 200° C. to 300° C. set as the set temperature. The inner control unit 81 generates a target temperature based on the set temperature and the ramp rate (step S5). The inner control unit 81 calculates the power ui to be output to the heater 42 so as to follow the generated target temperature, that is, such that the input inner temperature approaches the target temperature (inner control: step S6). The power ui is an example of the “first power.” The inner control unit 81 is an example of a first control unit that calculates the first power to be output to the heater 42 disposed in the processing container 10 such that the first temperature approaches the target temperature.

The outer control unit 82 inputs the acquired measured value of the outer temperature (step S7). The upper temperature limit may be stored in advance in a RAM of the control apparatus 90 to be described later. The upper temperature limit is set to a temperature lower than the excess temperature. The excess temperature is, for example, 1,050° C., and when the excess temperature is exceeded, the control apparatus 90 shuts down the heater 42 to stop heating by the heater 42 due to a safety problem. The upper temperature limit is set to, for example, 950° C. lower than the excess temperature.

The outer control unit 82 calculates the power uo to be output to the heater 42 such that the input outer temperature follows the upper temperature limit (outer control: step S8). The power uo is an example of the “second power.” The outer control unit 82 is an example of a second control unit that calculates the second power to be output to the heater 42 such that the second temperature approaches the upper temperature limit.

The output unit 83 inputs the excessive temperature rise flag set by the prediction unit 92 (step S9), and outputs either the power ui or the power uo to the heater 42 as a command value (control input value) based on the excessive temperature rise flag (step S10). When a predicted value of the outer temperature is less than the upper temperature limit, the output unit 83 outputs the power ui based on the excessive temperature rise flag set to 0. When the predicted value of the outer temperature is equal to or higher than the upper temperature limit, the output unit 83 outputs the power uo based on the excessive temperature rise flag set to 1. Thus, the heater 42 is controlled using the power ui or the power uo as a command value (control input value) (step S11).

(Prediction Unit)

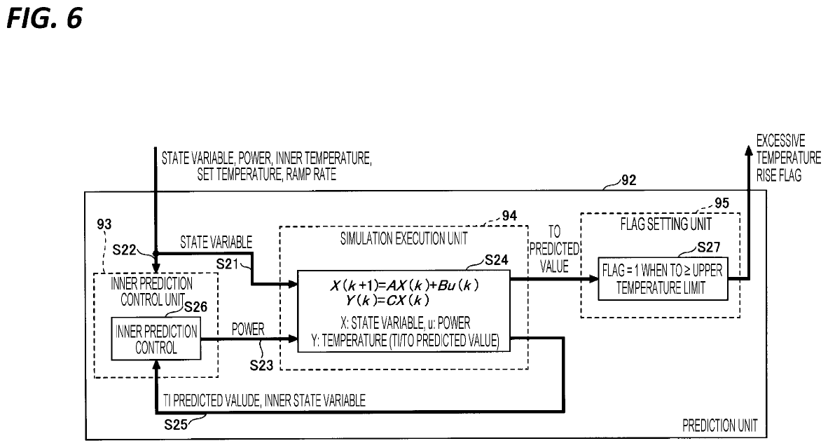

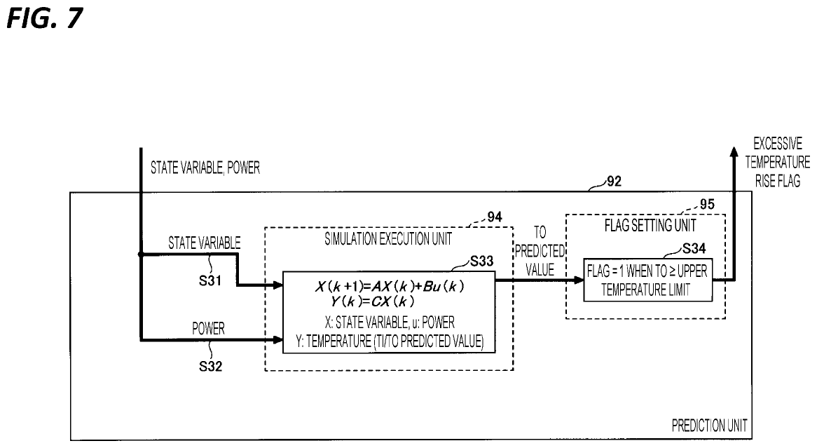

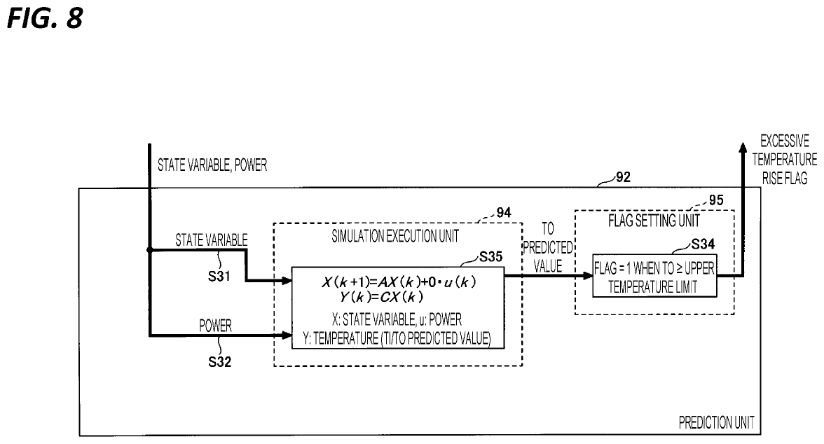

A configuration of the prediction unit 92 and a control method of Operation Examples 1 to 3 will be described with reference to FIGS. 6 to 8. FIG. 6 is a diagram illustrating a configuration and Operation Example 1 of the prediction unit 92 of the control apparatus 90 according to the first embodiment. FIG. 7 is a diagram illustrating a configuration and Operation Example 2 of the prediction unit 92 of the control apparatus 90 according to the first embodiment. FIG. 8 is a diagram illustrating a configuration and Operation Example 3 of the prediction unit 92 of the control apparatus 90 according to the first embodiment.

(Operation Example 1 of Prediction Unit)

The prediction unit 92 illustrated in FIG. 6 includes an inner prediction control unit 93, a simulation execution unit 94, and a flag setting unit 95, and is executed every predetermined cycle. The simulation execution unit 94 inputs the state variable from the control unit 80 (step S21). The inner prediction control unit 93 inputs the set temperature, the ramp rate, and the power from the control unit 80 (step S22). The state variable includes at least information on the outer temperature (including an initial value) and may further include information on the inner temperature. The power is information on the power output to the heater 42 (including an initial value).

The simulation execution unit 94 further inputs the power u predicted by the inner prediction control unit 93 to a prediction model (step S23). The simulation execution unit 94 predicts the outer temperature and the inner temperature for a given time obtained by dividing a predetermined time by the number of repetition times n (n≥1) (step S24). By calculation of the number of repetition times n of step S24, a predicted value of the outer temperature at the predetermined time ahead and a predicted value of the inner temperature at the predetermined time ahead are calculated. That is, the temperature Y calculated by the simulation execution unit 94 using the prediction model includes a predicted value of the outer temperature (TO predicted value) at a given time ahead and a predicted value of the inner temperature (TI predicted value) at a given time ahead.

The simulation execution unit 94 calculates a predicted value of the outer temperature and a predicted value of the inner temperature at a given time ahead. Therefore, the simulation execution unit 94 prepares in advance a prediction model including the constant A and the constant B used in Equation (1) for calculating the state variable at a given time ahead and the constant C used in Equation (2) for calculating a predicted value of the outer temperature at a given time ahead and a predicted value of the inner temperature at a given time ahead. The constants A, B, and C in Equation (1) may be different between Equation (1) for calculating a predicted value of the outer temperature at a given time ahead and Equation (1) for calculating a predicted value of the inner temperature at a given time ahead.

The state variable at a given time ahead is calculated by Equation (1).

X(k+1)=AX(k)+Bu(k) (1)

The outer temperature is calculated by Equation (2).

Y(k)=CX(k) (2)

k indicates the number of calculation times performed by the simulation execution unit 94, and when k=0, it indicates the current time point. When k=n, it indicates a predetermined time ahead. An increase of k by 1 indicates the lapse of a given time. For example, assuming that a predetermined time ahead is 1 minute ahead, and the number of repetition times n is 15, k+1 indicates a time point after the lapse of a given time of 4 seconds from k. When calculating a predicted value of the outer temperature (TO predicted value), information on the power to be output to the heater 42 by inner control executed by the inner control unit 81 is input to u in Equation (1). Information on the power input at the initial time when k=0 is set to u in Equation (1). By inputting X(k+1) calculated by Equation (1) into Equation (2), what degree the outer temperature at a given time ahead will be is predicted to calculate a predicted value of the outer temperature. Calculation of a predicted value of the inner temperature (TI predicted value) will be described later.

The prediction model is defined by Equations (1) and (2). The simulation execution unit 94 inputs the state variable X(k+1) at a given time ahead (k+1), calculated by inputting the state variable X and the power information to the prediction model of Equation (1) and Equation (2), into Equation (2). The outer temperature at a given time ahead Y(k+1) is calculated by Y(k+1)=CX(k+1) of Equation (2). Y(k+1) of the outer temperature is a predicted value of the outer temperature (TO predicted value).

In Operation Example 1, the prediction model may predict the inner temperature according to Equations (1) and (2). In Operation example 1, the simulation execution unit 94 calculates not only a predicted value of the outer temperature at a given time ahead, but also a predicted value of the inner temperature at a given time ahead (step S24). Y(k+1) of the inner temperature is a predicted value of the inner temperature (TI predicted value).

The predicted value of the inner temperature (TI predicted value) calculated by the simulation execution unit 94 is input to the inner prediction control unit 93 together with the state variable X(k+1) of the inner temperature at a given time ahead (step S25). The inner prediction control unit 93 further inputs the set temperature and the ramp rate (step S22). In Operation Example 1, the inner prediction control unit 93 sets a target temperature based on the set temperature and the ramp rate. The inner prediction control unit 93 calculates the power to be output to the heater 42 such that the TI predicted value approaches the target temperature based on the TI predicted value and the state variable X(k+1) of the inner temperature at a given time ahead (step S26).

The inner prediction control unit 93 outputs the calculated power, and the simulation execution unit 94 inputs the calculated power to u in Equation (1) of the prediction model (step S23). The simulation execution unit 94 inputs the input power to the prediction model represented in Equation (1) to calculate the state variable X(k+1) at a given time ahead (k+1). By inputting X(k+1) calculated by Equation (1) into Equation (2), what degree the inner temperature at a given time ahead will be is predicted to calculate a predicted value of the inner temperature (step S24). In this way, in Operation Example 1, Y(k+1) represented in Equation (2) includes a predicted value of the inner temperature at a given time ahead, and a predicted value of the outer temperature at a given time ahead.

The inner prediction control unit 93 and the simulation execution unit 94 repeat the process of calculating a predicted value of the inner temperature and a predicted value of the outer temperature up to, for example, 1 minute ahead every 4 seconds. However, the repetition cycle is not limited to every 4 seconds, but may be any other preset predetermined cycle. Further, the calculation of a predicted value is not limited to 1 minute from a given time point, but may be any other predetermined time. The flag setting unit 95 updates the setting of the excessive temperature rise flag at a predetermined cycle.

The flag setting unit 95 sets the excessive temperature rise flag to 1 when the predicted value of the outer temperature (TO predicted value) calculated by the simulation executing unit 94 is equal to or higher than the upper temperature limit (step S27). When the predicted value of the outer temperature is less than the upper temperature limit, the excessive temperature rise flag is left at the initial value of 0. In the determination in step S27, the excessive temperature rise flag is set to 1 when the predicted value of the outer temperature (TO predicted value) calculated by the simulation execution unit 94 when k=n is equal to or higher than the upper temperature limit. Alternatively, in the determination in step S27, the excessive temperature rise flag may be set to 1 when the predicted value of the outer temperature (TO predicted value) calculated respectively by the simulation execution unit 94 when k=1-n is equal to or higher than the upper temperature limit. The excessive temperature rise flag is input to the output unit 83 of the control unit 80 (step S9 in FIG. 5).

As described above, the output unit 83 outputs either the first power calculated by the inner control unit 81 or the second power calculated by the outer control unit 82 of the control unit 80 to the heater 42 of the heat treatment apparatus 1 according to the excessive temperature rise flag set by the prediction unit 92.

(Operation Example 2 of Prediction Unit)

The prediction unit 92 illustrated in FIG. 7 is different from the prediction unit 92 illustrated in FIG. 6 in that it does not include the inner prediction control unit 93. The prediction unit 92 includes the simulation execution unit 94 and the flag setting unit 95. The simulation execution unit 94 inputs the state variable acquired from the control unit 80 as an initial value into a prediction model (step S31), and always inputs the power to be output to the heater 42 into the prediction model (step S32). The simulation execution unit 94 calculates a predicted value of the outer temperature (TO predicted value) at a predetermined time ahead, from the acquired measured value of the outer temperature based on the prediction model (step S33). The flag setting unit 95 sets the excessive temperature rise flag to 1 when the predicted value of the outer temperature (TO predicted value) calculated by the simulation execution unit 94 is equal to or higher than the upper temperature limit (step S34). When the predicted value of the outer temperature is less than the upper temperature limit, the excessive temperature rise flag is left at the initial value of 0. The excessive temperature rise flag is input to the output unit 83 of the control unit 80 (step S9 in FIG. 5).

The prediction model used by the simulation execution unit 94 is the same as the prediction model (Equation (1) and Equation (2)) used by the simulation execution unit 94 illustrated in FIG. 6. However, in Operation Example 2 of the prediction unit 92, a predicted value of the outer temperature (TO predicted value) is calculated by the prediction model, but a predicted value of the inner temperature (TI predicted value) is not calculated by the prediction model. Thus, the operation of the inner prediction control unit 93 illustrated in FIG. 6 may be omitted. Accordingly, in Operation Example 2 of the prediction unit 92, the load of processing may be reduced as compared with the prediction unit 92 illustrated in FIG. 6. In Operation Example 2 and Operation Example 3 (see FIG. 8) of the prediction unit 92, the simulation execution unit 94 repeats the process of calculating a predicted value of the outer temperature at a predetermined time ahead such as, for example, 1 minute in a predetermined cycle such as every 4 seconds. The flag setting unit 95 updates the setting of the excessive temperature rise flag at a predetermined cycle.

(Operation Example 3 of Prediction Unit)

In Operation Example 3, Equation (1) of a prediction model illustrated in FIG. 8 differs from Equation (1) of the prediction model illustrated in FIG. 7 in that the constant B of the term power u is 0, but the other configuration is the same as that of Operation Example 2 illustrated in FIG. 7. That is, the simulation execution unit 94 inputs the state variable acquired from the control unit 80 as an initial value into a prediction model (step S31), and always inputs the power to be output to the heater 42 into the prediction model (step S32). The simulation execution unit 94 updates the state variable without using power information based on Equation (1) of the prediction model and calculates a predicted value of the outer temperature at a given time ahead by Equation (2) (step S35).

That is, the simulation execution unit 94 does not need to use the initial value of the input power since the power term is 0 when calculating the outer temperature Y(k+1) at a given time ahead, based on the prediction model of Equations (1) and (2). Thus, the prediction unit 92 illustrated in FIG. 8 may calculate a predicted value of the outer temperature at a given time ahead only by the state variable. The operation of the flag setting unit 95 is the same as that of Operation Examples 1 and 2, and thus, the description thereof will be omitted.

[Simulation Results]

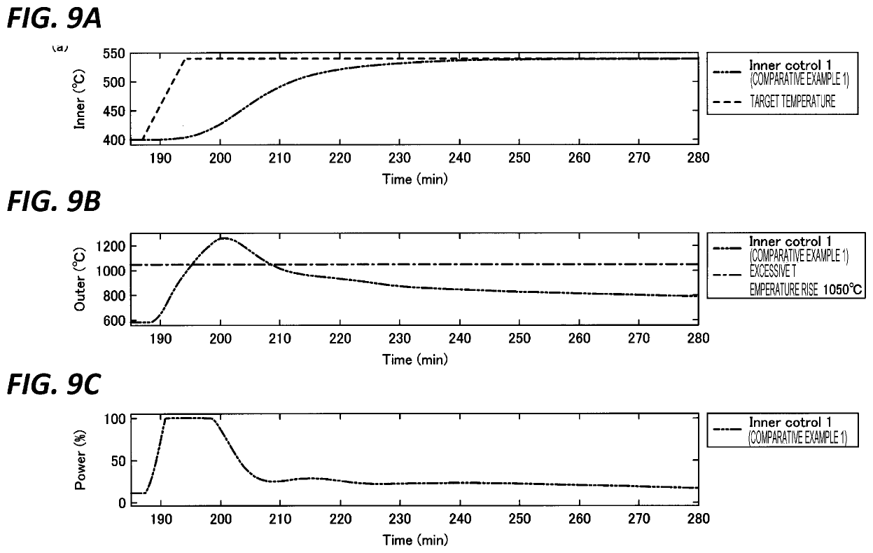

FIGS. 9A to 11C illustrate the results of simulations performed for a control method (in a case of Operation Example 3 of the prediction unit) of the heat treatment apparatus 1 according to Comparative Examples 1 and 2 and the first embodiment. FIGS. 9A to 9C are diagrams illustrating an example of the simulation results by control according to Comparative Example 1. Comparative Example 1 is a control method of the heat treatment apparatus 1 of transferring heat from the outer region to the inner region to raise the inner temperature to a target temperature by controlling the power of the heater 42 only by the control of the inner control unit 81.

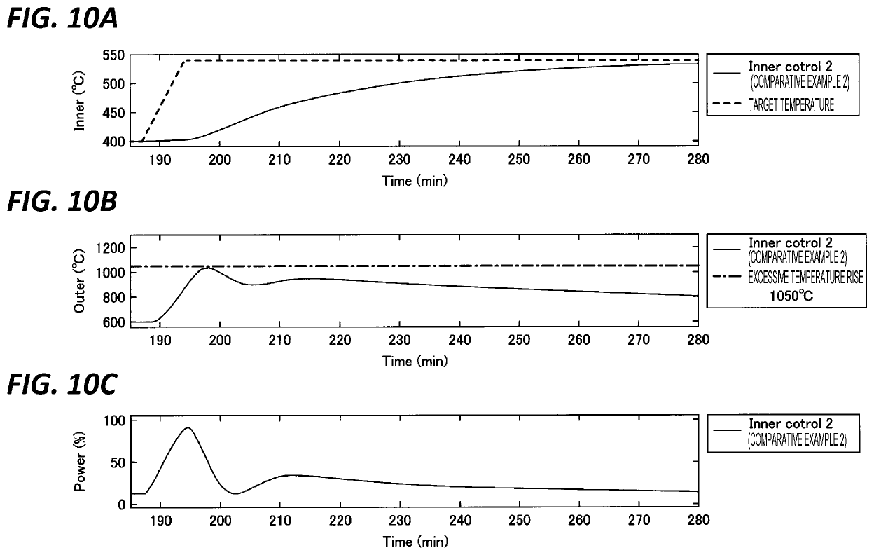

FIGS. 10A to 10C are diagrams illustrating an example of the simulation results by control according to Comparative Example 2. Comparative Example 2 is a control method of slowly increasing the power of the heater 42 such that the outer temperature does not exceed 1,050° C.

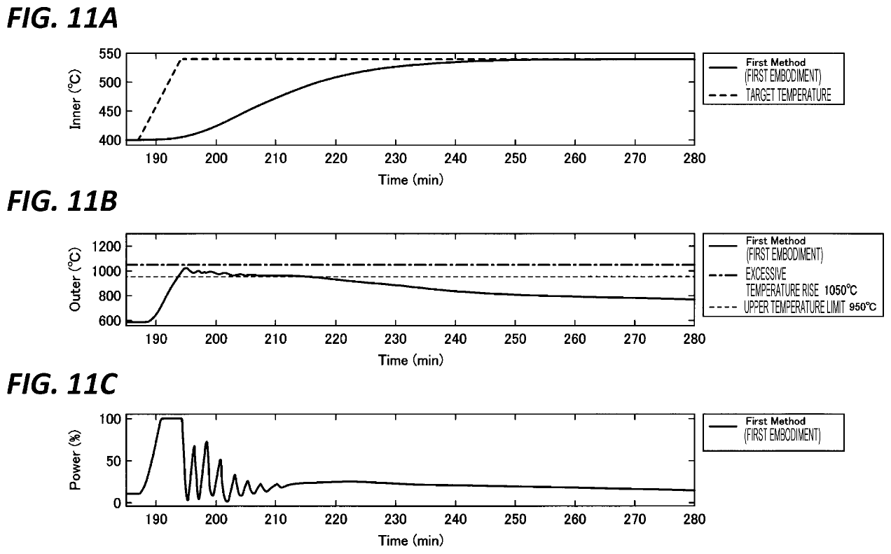

FIGS. 11A to 11C are diagrams illustrating an example of the simulation results of a control method of the heat treatment apparatus 1 by the control apparatus 90 according to the first embodiment. The first embodiment is the control method of the heat treatment apparatus 1 in a case of Operation Example 3 (FIG. 8) of the prediction unit 92. The operation of the control unit 80 of the first embodiment is as illustrated in FIG. 5.

As the simulation conditions, in any case, the simulation was performed by creating a prediction model in a case of forming a molybdenum film in the heat treatment apparatus 1. Further, the recipe (set temperature and ramp rate) was set to raise the inner temperature from 400° C. to 540° C. In all of Comparative Examples 1 and 2 and the first embodiment, the power of the heater 42 was controlled such that the inner temperature approaches a target temperature. Further, the excess temperature was set to 1,050° C., and the upper temperature limit was set to 950° C.

In FIGS. 9A, 10A, and 11A, the horizontal axis represents the process time, and the vertical axis represents the inner temperature. In FIGS. 9B, 10B, and 11B, the horizontal axis represents the process time, and the vertical axis represents the outer temperature. In FIGS. 9C, 10C and 11C, the horizontal axis represents the process time, and the vertical axis represents the power output to the heater 42.

As a result, in a case of Comparative Example 1, the inner temperature of the solid line illustrated in FIG. 9A is controlled to converge to the target temperature of the dotted line only by the control of the inner control unit 81. However, heat transfer from the outer region where the heater 42 is disposed to the inner region is poor due to reflection of the molybdenum film adhered to the inner region of the tubular member 2. Hence, as illustrated in FIG. 9C, the power output to the heater 42 is largely controlled such that the inner temperature converges to the target temperature quickly. Therefore, the outer temperature illustrated in FIG. 9B exceeds the excess temperature of 1,050° C., and due to a safety problem, the heater 42 is shut down to stop heating by the heater 42.

In a case of Comparative Example 2, the power of the heater 42 is slowly increased such that the outer temperature does not exceed 1,050° C. Therefore, as illustrated in FIG. 10C, the power output to the heater 42 is controlled to be gradually increased as compared with the power illustrated in FIG. 9C. As a result, in a case of Comparative Example 2, the outer temperature illustrated in FIG. 10B does not exceed the excess temperature of 1,050° C. However, it takes a time for the inner temperature of the solid line illustrated in FIG. 10A to converges to the target temperature of the dotted line as compared with the inner temperature of the solid line illustrated in FIG. 9A. This causes a deterioration in productivity.

In a case of the present embodiment, in the initial stage, the inner temperature of the solid line illustrated in FIG. 11A is controlled to converge to the target temperature. Further, with respect to the outer temperature as illustrated in FIG. 11B, the process of predicting the outer temperature at a time point a predetermined time ahead of the current time point is repeated at a predetermined cycle. Then, when a predicted value of the outer temperature exceeds the upper temperature limit, it is predicted that the outer temperature will exceed the upper temperature limit after the predetermined time elapses, and as illustrated in FIG. 11C, the power of the heater 42 is controlled to be suppressed such that the outer temperature does not exceed the upper temperature limit. Thus, an excessive rise in the outer temperature may be avoided. As a result, the time until the inner temperature converges to the target temperature as illustrated in FIG. 11A is as fast as Comparative Example 1 illustrated in FIG. 9A while avoiding the outer temperature from exceeding the excess temperature as illustrated in FIG. 11B, which may prevent a deterioration in productivity. From the above, in the control method of the heat treatment apparatus 1 according to the first embodiment, an excessive temperature rise inside the processing container 10 may be avoided without causing a delay in temperature control in the heat treatment apparatus 1.

### Second Embodiment

[Control Device]

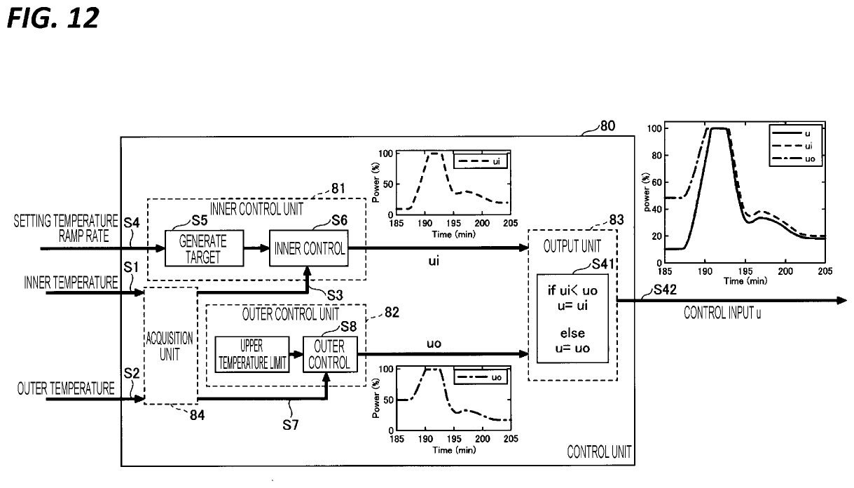

Next, the temperature control of the control apparatus 90 of a second embodiment when no prediction model is used will be described with reference to FIG. 12. FIG. 12 illustrates the control unit 80 of the control apparatus 90 according to a second embodiment. The control apparatus 90 according to the second embodiment does not include a prediction unit.

The control unit 80 includes the acquisition unit 84, the inner control unit 81, the outer control unit 82, and the output unit 83. The acquisition unit 84 acquires the inner temperature (TI temperature) measured by the temperature sensor 60 in the tubular member 2 and the outer temperature (TO temperature) measured by the temperature sensor 70 in the processing container 10 outside the tubular member 2 (steps S1 and S2). The measured inner temperature and outer temperature may be acquired repeatedly at timings corresponding to a predetermined cycle (e.g., 4 seconds), or may be acquired repeatedly at timings unrelated of the predetermined cycle. When the step number illustrated in FIG. 12 is the same as the step number illustrated in FIG. 5, this indicates the same processing.

The inner control unit 81 inputs the measured value of the inner temperature (step S3), and inputs the set temperature and the ramp rate (step S4). The inner control unit 81 generates a target temperature based on the set temperature and the ramp rate (step S5). The inner control unit 81 calculates the power ui to be output to the heater 42 disposed in the processing container 10 such that the inner temperature approaches the target temperature based on the acquired measured value of the inner temperature (step S6). The power ui is an example of the first power.

The outer control unit 82 inputs the measured value of the outer temperature (step S7), and calculates the power uo to be output to the heater 42 such that the outer temperature approaches the upper temperature limit based on the acquired measured value of the outer temperature (step S8). The power uo is an example of the second power.

The output unit 83 outputs the power ui or the power uo to the heater 42 based on a magnitude relationship between the power ui and the power uo (step S41). The output unit 83 outputs the power ui to the heater 42 as a control input value (power u) for the heater 42 when the power ui is smaller than the power uo. The output unit 83 outputs the power uo to the heater 42 as a control input value (power u) for the heater 42 when the power ui is equal to or greater than the power uo.

Each of the acquisition unit 84, the inner control unit 81, the outer control unit 82, and the output unit 83 repeatedly performs the operation thereof at a predetermined cycle.

For example, the graph of FIG. 12 illustrates an example of the power ui and the power uo. Meanwhile, the power u (control input value) output to the heater 42 illustrated in FIG. 12 is switched to the lower one of the power ui and the power uo.

[Simulation Results]

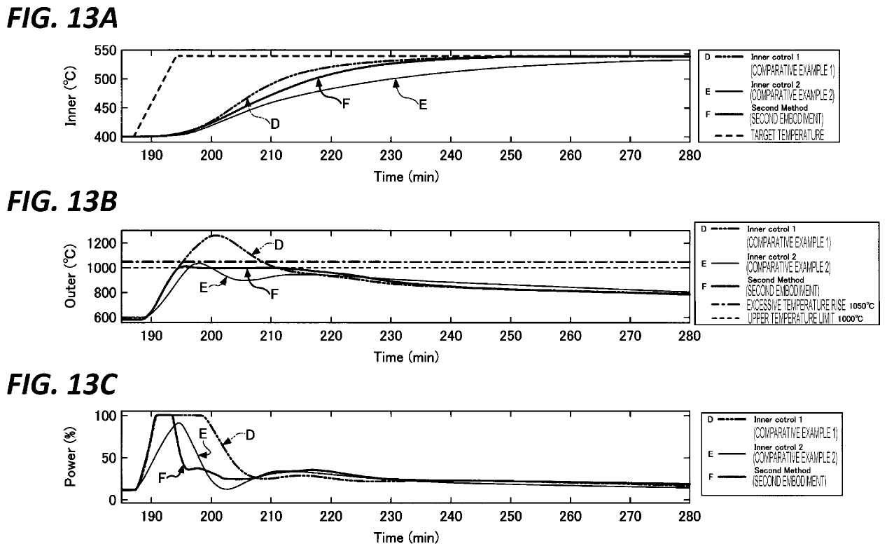

FIGS. 13A to 13C illustrate the results of simulations performed for a control method (with no prediction unit) of the heat treatment apparatus 1 according to Comparative Examples 1 and 2 and the second embodiment. FIGS. 13A to 13C are diagrams illustrating an example of the simulation results by the control apparatus 90 according to Comparative Examples 1 and 2 and the second embodiment. Comparative Examples 1 and 2 are the same as the control method described in the first embodiment.

That is, Comparative Example 1 is a control method of the heat treatment apparatus 1 of transferring heat from the outer region to the inner region to raise the inner temperature to a target temperature by controlling the power of the heater 42. Comparative Example 2 is a control method of the heat treatment apparatus 1 of slowly increasing the power of the heater 42 such that the outer temperature does not exceed 1,050° C. The present embodiment is a control method of the heat treatment apparatus 1 of controlling the power of the heater 42 to the lower one of the power ui and the power uo.

In FIG. 13A, the horizontal axis represents the process time, and the vertical axis represents the inner temperature. In FIG. 13B, the horizontal axis represents the process time, and the vertical axis represents the outer temperature. In FIG. 13C, the horizontal axis represents the process time, and the vertical axis represents the power output to the heater 42.

In the control method of Comparative Example 1 represented by the line D in FIGS. 13A to 13C, the power of the heater 42 is controlled to be increased such that the inner temperature quickly converges to the target temperature of the dotted line as represented by the line D in FIGS. 13A and 13C. Therefore, the outer temperature exceeds the excess temperature of 1,050° C. as represented by the line D in FIG. 13B, and the heater 42 stops.

In the control method of Comparative Example 2 represented by the line E in FIGS. 13A to 13C, the power of the heater 42 is controlled to be gradually increased so as to slowly raise the inner temperature as represented by the line E in FIGS. 13A and 13C. Therefore, the outer temperature does not exceed the excess temperature of 1,050° C. as represented by the line E in FIG. 13B, but it takes a time for the inner temperature to converge to the target temperature as represented by the line E in FIG. 13A, which causes a deterioration in productivity.

In the control method of the second embodiment represented by the line F in FIGS. 13A to 13C, the power u output to the heater 42 is controlled to be switched to the lower one of the power ui and the power uo as represented by the line F in FIG. 13C. As a result, it takes a short time for the inner temperature to converge to the target temperature as represented by the line F in FIG. 13A while avoiding the outer temperature from exceeding the excess temperature of 1,050° C. as represented by the line F in FIG. 13B, which may prevent a deterioration in productivity.

With the control method of the heat treatment apparatus 1 according to the second embodiment, the outer control unit 82 controls the power uo to be increased since a difference between the outer temperature and the upper temperature limit is large in the initial stage of this control. Meanwhile, since the inner control unit 81 controls the power ui according to the target temperature, and since a difference between the target temperature and the inner temperature is small, the power ui is controlled to be reduced under the inner control. As a result, the power ui is output to the heater 42 in the initial stage of this control.

The power ui controlled by the inner control unit 81 is increased rapidly when the inner temperature starts to rise. Meanwhile, the power uo controlled by the outer control unit 82 is reduced when the outer temperature approaches the upper temperature limit.

Thus, a magnitude relationship between the power ui and the power uo is exchanged, and the power uo is output to the heater 42. In this way, by outputting any one power to the heater 42 by switching from the power ui in the initial stage to the power uo from the middle of this control, the power uo is used from the middle such that the outer temperature is controlled to approach the upper temperature limit.

After that, since the power ui is gradually reduced, in the final stage of this control, the magnitude relationship between the power ui and the power uo is exchanged again, and finally the switched power ui is output to the heater 42.

Thus, with the control method of the heat treatment apparatus 1 according to the second embodiment, it takes a short time for the inner temperature to converge to the set temperature while avoiding the outer temperature from exceeding the excess temperature, which may prevent a deterioration in productivity.

As described above, with the control method of the film forming apparatus according to the first and second embodiments, an excessive temperature rise inside the processing container may be avoided even in the film forming apparatus having a dual structure of the processing container and the tubular member. Further, it takes a short time for the inner temperature to converge to the target temperature, which may prevent a deterioration in productivity.

The control method of the film forming apparatus according to the first and second embodiments is suitable for a film forming apparatus that has a dual structure of the processing container 10 and the tubular member 2 similar to the heat treatment apparatus 1 of FIG. 1 and that forms a metal film having a reflectance close to 1, such as a molybdenum film, on the wafer W accommodated in the tubular member 2. It may also be used for a process of forming a metal film such as a tungsten or niobium film other than the molybdenum film.

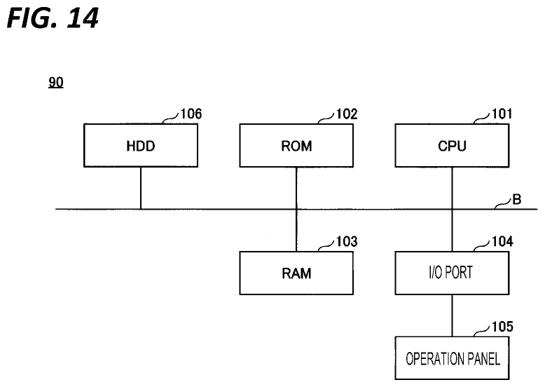

Finally, an example of a hardware configuration of the control apparatus 90 that executes the control method of the film forming apparatus according to the present disclosure will be described with reference to FIG. 14. The control apparatus 90 includes a Central Processing Unit (CPU) 101, a Read Only Memory (ROM) 102, a Random Access Memory (RAM) 103, a I/O port 104, an operation panel 105, and a Hard Disk Drive (HDD)106. These respective units are connected by a bus B.

The CPU 101 controls various operations and processings such as a film forming processing and a cleaning processing of the film forming apparatus such as the heat treatment apparatus 1 based on various programs read out from the RAM 103 or recipes that stipulate the order of processings such as the film forming processing and the cleaning processing. The programs include a program for executing the control method of the film forming apparatus according to the first and second embodiments. The CPU 101 executes the control method of the film forming apparatus according to the first and second embodiments based on these programs read out from the RAM 103.

The ROM 102 is configured with an electrically erasable programmable ROM (EEPROM), a flash memory, or a hard disk, and is a storage medium that stores the programs or recipes of the CPU 101. The RAM 103 functions as a work area of the CPU 101.

The I/O port 104 acquires various detected values such as the temperature, pressure, and gas flow rate from various sensors attached to the film forming apparatus and transmits the values to the CPU 101. Further, the I/O port 104 outputs a control signal output by the CPU 101 to each unit of the film forming apparatus. Further, the operation panel 105 through which an operator (user) operates the film forming apparatus is connected to the I/O port 104.

The HDD 106 is an auxiliary storage device, and may store, process recipes or programs therein. Further, the HDD 106 may store log information of measured values from various sensors. FIG. 14 may be a hardware configuration of the control unit 80 and/or the prediction unit 92 in the control apparatus 90.

According to an aspect, it is possible to avoid an excessive temperature rise inside a processing container without causing a delay in temperature control in a film forming apparatus.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A method of controlling a film forming apparatus, the method comprising:
(a) acquiring a first temperature measured by a first temperature sensor in a tube inside a processing container of the film forming apparatus;
(b) calculating a first power to be output to a heater disposed in the processing container such that the first temperature approaches a target temperature, based on the first temperature acquired in (a);
(c) acquiring a second temperature measured by a second temperature sensor provided outside the tube in the processing container;
(d) calculating a second power to be output to the heater such that the second temperature approaches an upper temperature limit, based on the second temperature acquired in (c);
(e) calculating a predicted value of the second temperature at a predetermined time ahead, from the second temperature acquired in (c), based on a prediction model that predicts at least the second temperature;
(f) outputting either the first power or the second power to the heater according to the predicted value of the second temperature calculated in (e); and
(g) repeating (a) to (f) in a predetermined cycle.

2. The method according to claim 1, wherein in (f), the first power is output to the heater when the predicted value of the second temperature is less than the upper temperature limit.

3. The method according to claim 1, wherein in (f), the second power is output to the heater when the predicted value of the second temperature is equal to or higher than the upper temperature limit.

4. The method according to claim 1, wherein the prediction model is capable of predicting the first temperature, and a state variable including information on the second temperature is input to the prediction model,
wherein the method further comprises:
(h) calculating a power to be output to the heater such that a predicted value of the first temperature calculated by the prediction model approaches the target temperature; and
(i) inputting the power calculated in (h) to the prediction model, and calculating a predicted value of the first temperature at a given time ahead, from the predicted value of the first temperature based on the prediction model, and
wherein (e) includes inputting the power calculated in (h) to the prediction model based on the predicted value of the first temperature calculated in (i), and repeating calculation of a predicted value of the second temperature at a given time ahead n(n≥1) times to calculate the predicted value of the second temperature at the predetermined time ahead.

5. The method according to claim 1, wherein the (e) includes inputting power information and a state variable including information on the second temperature to the prediction model, and calculating the predicted value of the second temperature at the predetermined time ahead, from the second temperature acquired in (c).

6. The method according to claim 1, wherein the (e) includes inputting a state variable including information on the second temperature to the prediction model, and calculating the predicted value of the second temperature at the predetermined time ahead, from the second temperature acquired in (c).

7. A method of controlling a film forming apparatus, the method comprising:
(a) acquiring a first temperature measured by a first temperature sensor in a tube inside a processing container of the film forming apparatus;
(b) calculating a first power to be output to a heater disposed in the processing container such that the first temperature approaches a target temperature, based on the first temperature acquired in (a);
(c) acquiring a second temperature measured by a second temperature sensor provided outside the tube in the processing container;
(d) calculating a second power to be output to the heater such that the second temperature approaches an upper temperature limit, based on the second temperature acquired in (c);
(e) outputting either the first power or the second power to the heater based on a magnitude relationship between the first power and the second power; and
(f) repeating (a) to (e) in a predetermined cycle.

8. The method according to claim 7, wherein the first power is output to the heater when the first power is smaller than the second power, and
the second power is output to the heater when the first power is equal to or greater than the second power.

9. The method according to claim 1, wherein the film forming apparatus forms a metal film.

10. The method according to claim 1, wherein the tube includes an inner tube that accommodates a substrate and an outer tube that surrounds the inner tube, and
a surface of the inner tube and an inner surface of the outer tube are covered with a film having a relatively high reflectance.

11. An apparatus for controlling a film forming apparatus, the apparatus comprising:
an acquisition circuitry configured to acquire a first temperature measured by a first temperature sensor in a tube inside a processing container of the film forming apparatus, and acquire a second temperature measured by a second temperature sensor provided outside the tube in the processing container;
a first control circuitry configured to calculate a first power to be output to a heater disposed in the processing container such that the first temperature approaches a target temperature based on the first temperature acquired by the acquisition circuitry;
a second control circuitry configured to calculate a second power to be output to the heater such that the second temperature approaches an upper temperature limit based on the second temperature acquired by the acquisition circuitry;
a prediction circuitry configured to calculate a predicted value of the second temperature at a predetermined time ahead, from the second temperature acquired by the acquisition circuitry, based on a prediction model that predicts at least the second temperature; and
an output circuitry configured to output either the first power or the second power to the heater according to the predicted value of the second temperature calculated by the prediction circuitry,
wherein each of the acquisition circuitry, the first control circuitry, the second control circuitry, the prediction circuitry, and the output circuitry repeatedly performs an operation thereof in a predetermined cycle.
